(19) United States
(12) Patent Application Publication
(10) Pub. No.: US 2010/0207187 A1
(43) Pub. Date: Aug. 19, 2010

(54) NONVOLATILE SEMICONDUCTOR MEMORY DEVICE

(75) Inventors: Nobutoshi Aoki, Yokohama-shi (JP); Masaki Kondo, Kawasaki-shi (JP); Takashi Izumida, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/644,821

(22) Filed: Dec. 22, 2009

(30) Foreign Application Priority Data
Feb. 19, 2009 (JP) 2009-036271

(51) Int. Cl. H01L 29/788

(52) U.S. Cl. 257/316; 257/E29.3

(57) ABSTRACT

A nonvolatile semiconductor memory device comprises a memory cell. The memory cell includes a first gate insulating film formed on a semiconductor substrate, a floating gate formed on the first gate insulating film, a second gate insulating film formed on the floating gate, and a control gate formed on the second gate insulating film. The floating gate includes a first semiconductor film which contacts the first gate insulating film, and a metal film stacked on the semiconductor film. An effective tunneling thickness between the semiconductor substrate and the floating gate in a read operation is thicker than an effective tunneling thickness between the semiconductor substrate and the floating in a write operation.

### CROSS-REFERENCE TO RELATED APPLICATION

This application is based upon and claims the benefit of priority from the prior Japanese Patent Application No. 2009-36271, filed on Feb. 19, 2009, the entire contents of which are incorporated herein by reference.

### BACKGROUND

Conventionally, in order to enhance capacitive coupling between a floating gate (hereinafter, “FG”) and a control gate (hereinafter, “CG”) in memory cells having a floating gate structure, it is necessary to have a large facing area between the FG and the CG. Accordingly, a shape that a part located above an STI (Shallow Trench Isolation) of the CG protrudes downwardly is employed (see JP2004-22819A). However, because of reduction of the memory cell size due to high integration of memories, when a distance between STIs becomes small, formation of insulators (hereinafter, “IPD”: Inter-Poly-Si Dielectrics) between the CG and the FG and burying thereof become difficult, it may be better that the CG have a planar structure. In this case, a CG-FG facing area and an area of an element region (hereinafter, “AA”) become substantially equal, so that a capacitive coupling ratio (hereinafter, “Cr”) between the FG and the CG decrease, resulting in problems in write, erase, and read operations. In order to overcome such problems, there is proposed a technique of increasing a tunnel current by thinning a tunnel insulator, but because the tunnel rate at the time of retention also increases due to the thinning of the insulator, the retention characteristics in a write state are deteriorated.

In contrast, polysilicon in which a dopant is doped is generally used as the FG. When a polysilicon electrode is used, in order to suppress any depletion at the time of write, erase, and read operation, a dopant with a high concentration (10²⁰ cm⁻³) is doped. However, it is difficult to dope a dopant with a sufficiently high concentration in the FG because of an effect that the dopant is sucked out from polysilicon to an insulating layer. Therefore, the FG becomes depleted at the time of write, erase, and read operations, and the retention characteristics are thus deteriorated.

### SUMMARY

A nonvolatile semiconductor memory device according to the first aspect of the present invention comprises a memory cell, the memory cell including: a semiconductor substrate; a first gate insulating film formed on the semiconductor substrate; a floating gate formed on the first gate insulating film; a second gate insulating film formed on the floating gate; and a control gate formed on the second gate insulating film, the floating gate comprising a first semiconductor film contacting the first gate insulating film, and a metal film stacked on the first semiconductor film, and an effective tunneling thickness between the semiconductor substrate and the floating gate in a read operation being thicker than an effective tunneling thickness between the semiconductor substrate and the floating gate in a write operation.

A nonvolatile semiconductor memory device according to the second aspect of the present invention comprises a memory cell, the memory cell including: a semiconductor substrate; a first gate insulating film formed on the semiconductor substrate; a floating gate formed on the first gate insulating film; a second gate insulating film formed on the floating gate; and a control gate formed on the second gate insulating film, the floating gate comprising a first semiconductor film contacting the first gate insulating film, and a metal film stacked on the first semiconductor film, and a concentration of a dopant in the first semiconductor film of the floating gate is substantially equal to or less than a concentration that causes an inversion layer to be formed in the vicinity of the first gate insulating film in a write operation, and is higher than a concentration that does not cause the inversion layer to be not formed in the vicinity of the first gate insulating film in a read operation.

A nonvolatile semiconductor memory device according to the third aspect of the present invention comprises a memory cell, the memory cell including: a semiconductor substrate; a first gate insulating film formed on the semiconductor substrate; a floating gate formed on the first gate insulating film; a second gate insulating film formed on the floating gate; and a control gate formed on the second gate insulating film, and the floating gate having a part in which a dopant is doped at a higher concentration in the vicinity of the second gate insulting film than another part in the vicinity of the first gate insulating film.

### BRIEF DESCRIPTION OF THE DRAWINGS

FIG. 1 is a cross-sectional view showing a memory cell of a nonvolatile semiconductor memory device according to a first embodiment;

FIG. 2 is a diagram for explaining a condition at the time of write operation of the nonvolatile semiconductor memory device of the first embodiment;

FIG. 3 is a diagram for explaining a condition at the time of read operation of the nonvolatile semiconductor memory device of the first embodiment;

FIGS. 4A to 4D are diagrams showing a manufacturing process of the memory cell of the nonvolatile semiconductor memory device of the first embodiment;

FIG. 5 is a cross-sectional view showing a memory cell of a nonvolatile semiconductor memory device according to a second embodiment;

FIGS. 6A to 6F are diagrams showing a manufacturing process of the memory cell of the nonvolatile semiconductor memory device of the second embodiment;

FIGS. 7A and 7B are cross-sectional views showing a memory cell of a nonvolatile semiconductor memory device according to a third embodiment;

FIG. 8 is a diagram for explaining a condition at the time of write operation of the nonvolatile semiconductor memory device of the third embodiment;

FIG. 9 is a diagram for explaining a condition at the time of read operation of the nonvolatile semiconductor memory device of the third embodiment;

FIG. 10 is a cross-sectional view showing a memory cell of a nonvolatile semiconductor memory device according to a fourth embodiment;

FIG. 11 is a cross-sectional view showing a memory cell of a nonvolatile semiconductor memory device according to a fifth embodiment;

FIG. 12 is a cross-sectional view showing a memory cell of a nonvolatile semiconductor memory device according to a sixth embodiment;

FIG. 13 is a diagram showing an example of an impurity concentration of a floating gate in the nonvolatile semiconductor memory device of the sixth embodiment; and

FIG. 14 is a diagram showing another example of an impurity concentration of a floating gate in the nonvolatile semiconductor memory device according to the sixth embodiment.

### DETAILED DESCRIPTION

An explanation will be given of embodiments of the present invention with reference to accompanying drawings.

### First Embodiment

### Structure of Memory Cell

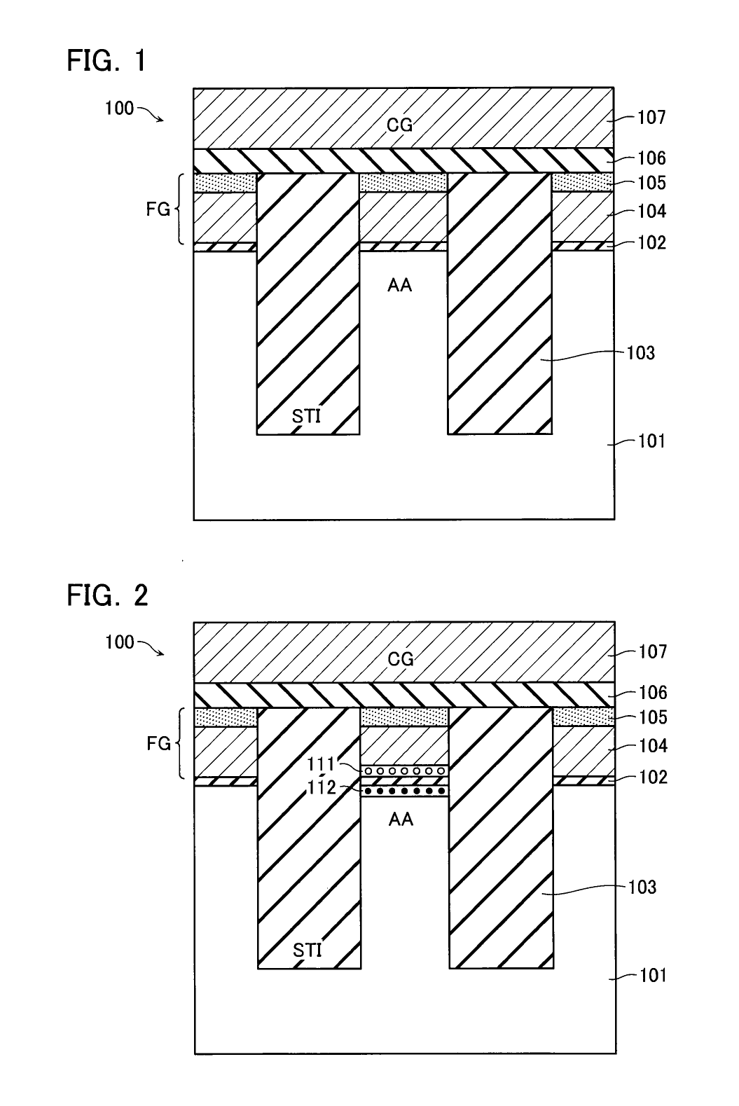

FIG. 1 is a cross-sectional view showing a memory cell 100 of a nonvolatile semiconductor memory device according to the first embodiment.

The memory cell 100 comprises a stacked body including a silicon (Si) substrate 101 which is a semiconductor substrate, a tunnel insulating film 102 which is a gate insulation layer formed on the substrate 101, an FG formed on an AA of the silicon substrate 101 via the tunnel insulating film 102, an IPD film 106 which is a second gate insulation film, and a CG 107. The FG comprises a first semiconductor film 104 formed of polysilicon, and a metal film 105 which contacts the IPD film 106 and which has a predetermined thickness. Portions of the memory cell 100 below the FG adjoining the direction in which the CG 107 extends are mutually divided from each other by an STI 103 orthogonal to the CG 107.

Providing the metal film 105 at a portion of the FG facing the CG 107 makes it possible to suppress an influence of depletion with respect to a capacitance between the FG and the CG.

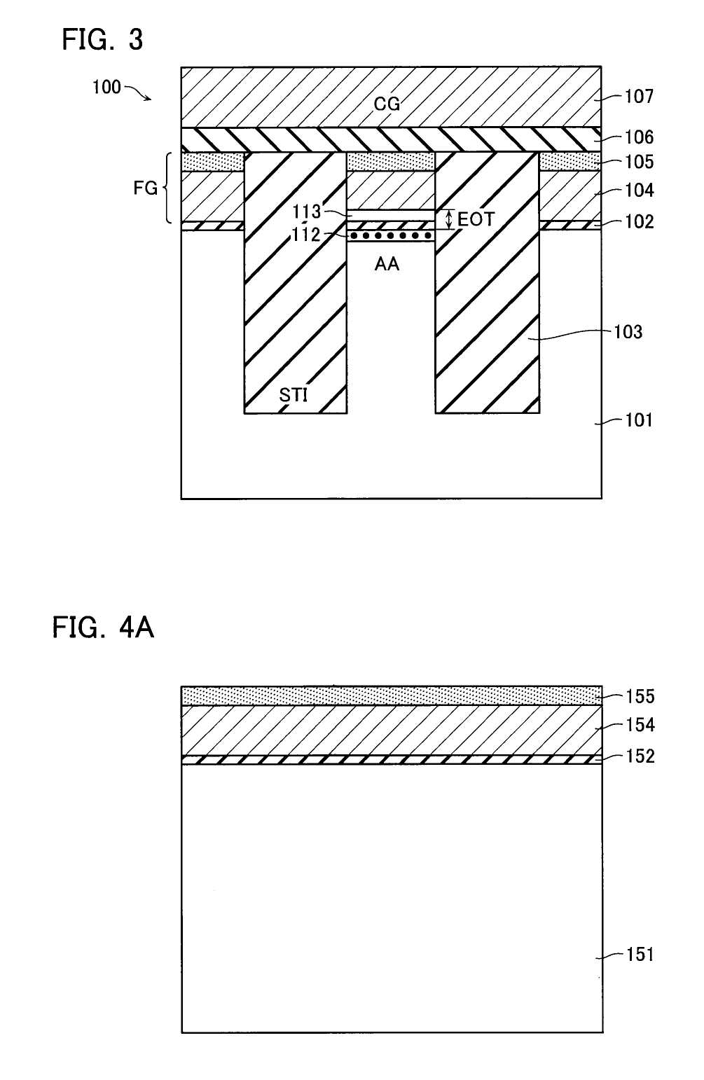

Next, an explanation will be given of a concentration of a dopant doped in the semiconductor film 104 of the FG in the memory cell 100 with reference to FIGS. 2 and 3.

FIGS. 2 and 3 are diagrams for explaining conditions at the time of write operation and read operation of the nonvolatile semiconductor memory device of the first embodiment.

In the memory cell 100, at the time of write operation, charges are accumulated by tunneling of a carrier flowing through the tunnel insulating film 102, so that a higher voltage in comparison with at the time of read operation is applied to the CG 107. Accordingly, the concentration of dopant doped in the semiconductor film 104 of the FG is set to be less than a concentration Npolymax (Vpgm) or equal in such a way that an inversion layer (hall) 111 is formed in the vicinity of the tunnel insulating film 102 shown in FIG. 2 in the semiconductor film 104 of the FG by a voltage Vpgm applied at the time of write operation. Moreover, the concentration of such a dopant is also set to be higher than a concentration Npolymin (Vread) in such a way that the inversion layer is not formed in the vicinity of the tunnel insulating film 102 shown in FIG. 3 in the semiconductor film 104 of the FG by a voltage Vread applied at the time of read operation. That is, the impurity concentration Npoly of the semiconductor film 104 of the FG is set to Npolymin (Vread)<Npoly<Npolymax (Vpgm).

Accordingly, a tunnel film thickness EOT effective at the time of read operation becomes equal to an addition of a physical film thickness of the tunnel insulating film 102 with a depletion layer 113 formed in the semiconductor film 104 of the FG. Conversely, at the time of write operation, an inversion layer (electron) 112 is formed in the semiconductor film 104 of the FG and in the AA of the silicon substrate 101 facing the semiconductor film 104, so that the effective tunneling thickness EOT which slightly varies depending on the quantum effect becomes substantially equal to the physical film thickness of the tunnel insulating film 102.

If the equivalent silicon oxide film (SiO₂) thickness of the tunnel insulating film 102 is Tox, a width of depletion layer at the time of read operation is tdep, a permittivity of the semiconductor film 104 is εSi, and a permittivity of a silicon oxide film is εox, then, an effective tunneling thickness EOT between the FG and the AA at the time of write operation and that at the time of read operation become EOT=Tox, EOT=Tread=Tox+tdep×εox/εsi, respectively. According to the first embodiment, the effective tunneling thickness EOT differs between at the time of write operation and at the time of read operation. By setting the concentration of the dopant doped in the semiconductor film in this fashion, the tunnel insulating film 102 can be thinned.

Conversely, in order to enhance the tunnel efficiency of charges at the time of write operation, it is effective to increase the electric field strength applied to the tunnel insulating film or to make the tunnel insulating film thin. However, when an area where the FG and the CG face with each other is flat, it is difficult to increase the capacitive coupling ratio Cr. Accordingly, if the electric field strength applied to the tunnel insulating film is increased, the electric field strength between the FG and the CG is also increased, resulting in increasing of charges leaking through the IPD film. Therefore, it is desirable to improve the tunnel efficiency by thinning of the effective tunneling thickness.

However, like the conventional technology, when a dopant is doped in polysilicon at a high concentration, because the width of a depletion layer is narrow, the effective tunneling thickness at the time of read operation becomes substantially equal to the equivalent silicon oxide film thickness of the tunnel insulating film itself. In this case, if the tunnel insulating film is thinned, erroneous writing occurs at the time of read operation.

In this point, according to the first embodiment, the effective tunneling thickness EOT at the time of write operation is the equivalent silicon oxide film thickness Tox of the tunnel insulating film itself, but the effective tunneling thickness EOT at the time of read operation is thickened by what corresponds to the depletion layer 113, thus overcoming the foregoing problem.

Furthermore, when it is left in a programming state, the inversion layer 112 of electrons is formed in the AA, and the electric field strength applied to the tunnel insulating film 102 is reduced, resulting in improvement of the retention characteristics.

As explained above, according to the first embodiment, it is possible to provide the nonvolatile semiconductor memory device having good write operation characteristics and retention characteristics.

Note that the concentration Npoly of the dopant doped in the semiconductor film 104 of the FG can be arbitrary set based on the thickness of the IPD film 106, the permittivity ε of a material, applied voltages Vpgm and Vread at the time of write operation and read operation, the equivalent silicon oxide film thickness Tox of the tunnel insulating film 102 itself, and the width tdep of the depletion layer 113 at the time of read operation, and the like. However, it is desirable to set such a concentration to 5×10¹⁸ cm⁻³ to 5×10¹⁹ cm⁻³.

<Manufacturing Method of Memory Cell>

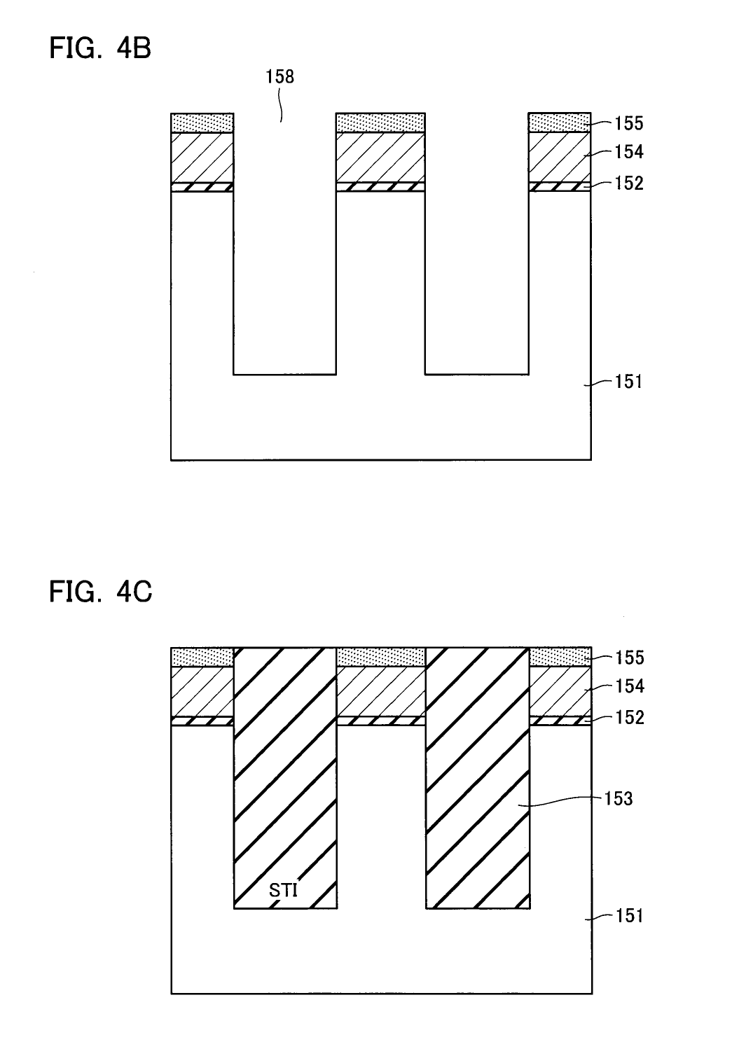

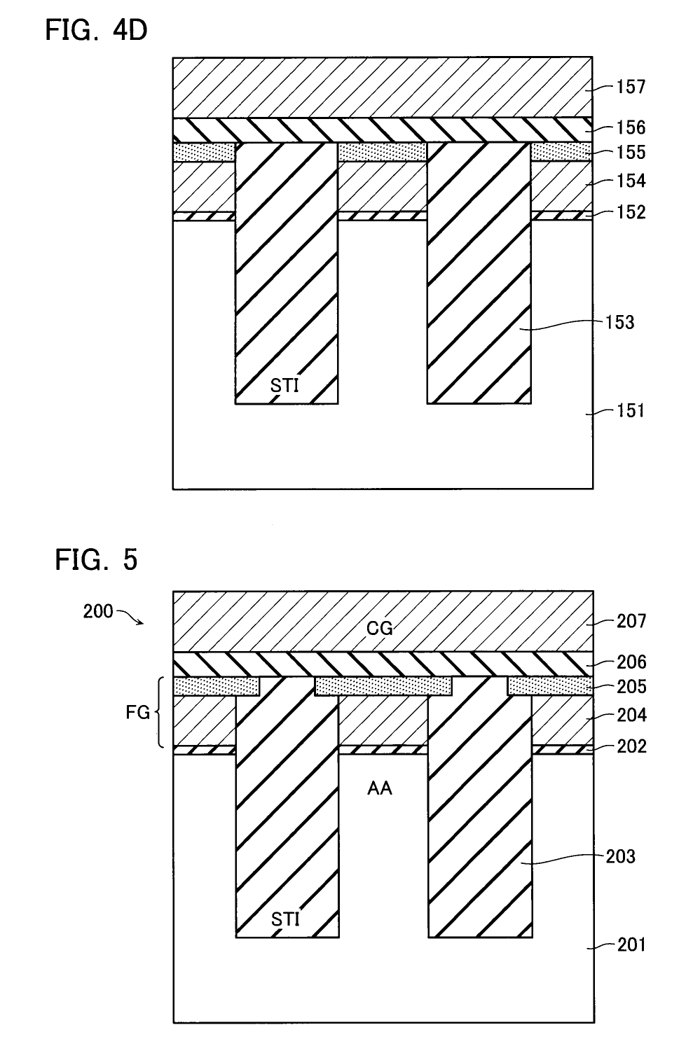

Next, an explanation will be given of the manufacturing method of the memory cell of the nonvolatile semiconductor memory device of the first embodiment with reference to FIGS. 4A to 4D.

First, as shown in FIG. 4A, a first insulating layer 152 which will is formed of SiO₂ and which will be the tunnel insulating film 102 (first gate insulating film), a semiconductor layer 154 which is formed of polysilicon and which will be the semiconductor film 104 of the FG, and a metal layer 155 which is formed of WSi and which will be the metal film 105 of the FG are successively deposited on a silicon substrate 151. Note that as the metal layer 155, instead of WSi, an arbitrary conducting body, such as Cu, Ti, Pt or TiN, can be used.

Next, as shown in FIG. 4B, a plurality of parallel trenches 158 each having a depth reaching the interior of the silicon substrate 151 are formed between adjoining memory cells 100 by RIE.

Subsequently, as shown in FIG. 4C, a buried insulating body 153 which is formed of SiO₂ or the like and which will be the insulating film 103 is buried in the trench 158 to form an STI. Thereafter, the upper face of the buried insulating body 153 is flattened by CMP. In the case of FIG. 4C, the metal layer 155 is used as the stopper for CMP, but a protective film formed of SiN or the like may be formed on the metal layer 155 as needed. In this case, however, it is necessary to remove the protective film later.

Finally, as shown in FIG. 4D, an IPD layer 156 which will be the IPD film 106 (second gate insulating film), and a semiconductor layer 157 which is formed of polysilicon and which will be the CG are successively deposited on the buried insulating body 153 and the metal layer 155. As the IPD layer 156, a stacked film of SiN and SiO₂ can be used, and a highly-dielectric film like HfO₂ or Al₂O₃, a stacked film of those, or a stacked film of a highly-dielectric film and SiO₂, SiN or the like can also be used.

Note that in the foregoing explanation, a doping step of a dopant to the semiconductor layer 154 is omitted, but the dopant can be doped by ion implantation after the semiconductor layer 154 is deposited, and can be doped simultaneously with deposition of the semiconductor layer 154.

According to the foregoing method, the STI is formed after the tunnel insulating film 102 and the FG are formed, but the memory cell 100 can be manufactured even if the tunnel insulating film 102 and the FG are formed after the STI is formed.

### Second Embodiment

### Structure of Memory Cell

FIG. 5 is a cross-sectional view showing a memory cell 200 of a nonvolatile semiconductor memory device according to the second embodiment.

The memory cell 200 has the same structure as that of the memory cell 100 of the first embodiment except that a metal film 205 of the FG is larger than a first semiconductor film 204 thereof.

According to the second embodiment, because the metal film 205 of the FG is larger than the semiconductor film 204, an area where the FG and the CG face with each other becomes larger than an area where the FG and the AA face with each other. As a result, the capacitance between the FG and the CG becomes larger than the capacitance between the FG and the AA, resulting in increasing of the capacitive coupling ratio Cr in comparison with the first embodiment.

Note that as the material of the metal layer 205, an arbitrary metal, such as TiN, TaN or a silicide like WSi can be used in consideration of the easiness of fabrication, the thermal stability, the tolerability against oxidation, the productivity like cost, and the consistency of an insulating film 203, an IPD film 206, or the like.

<Manufacturing Method of Memory Cell>

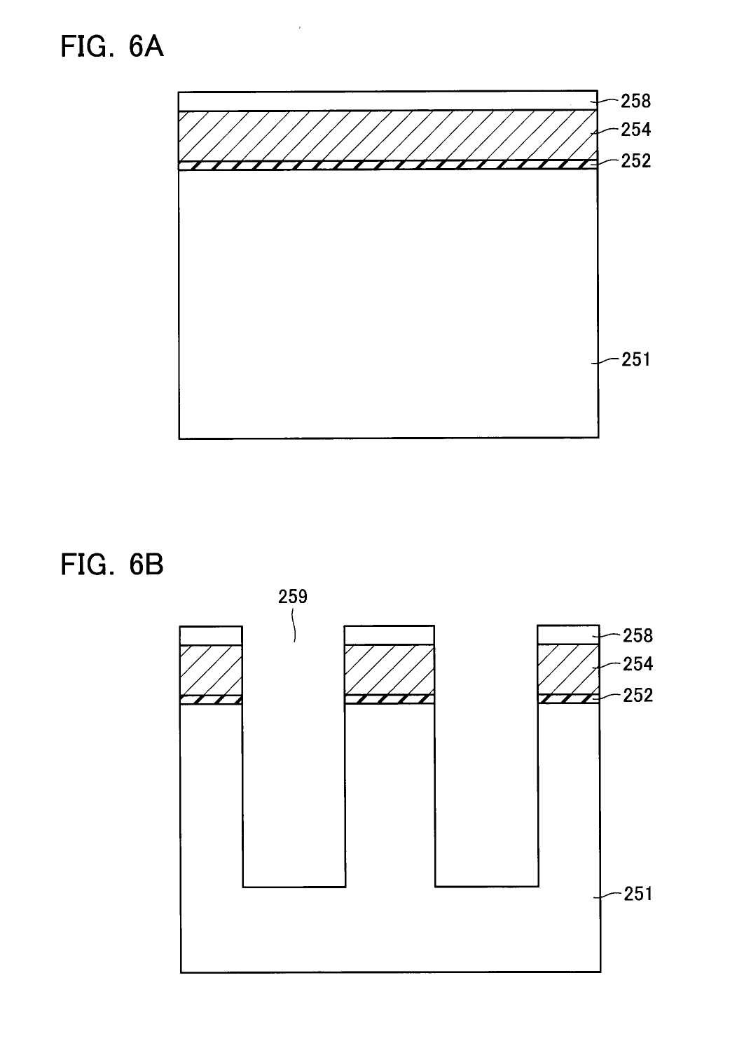

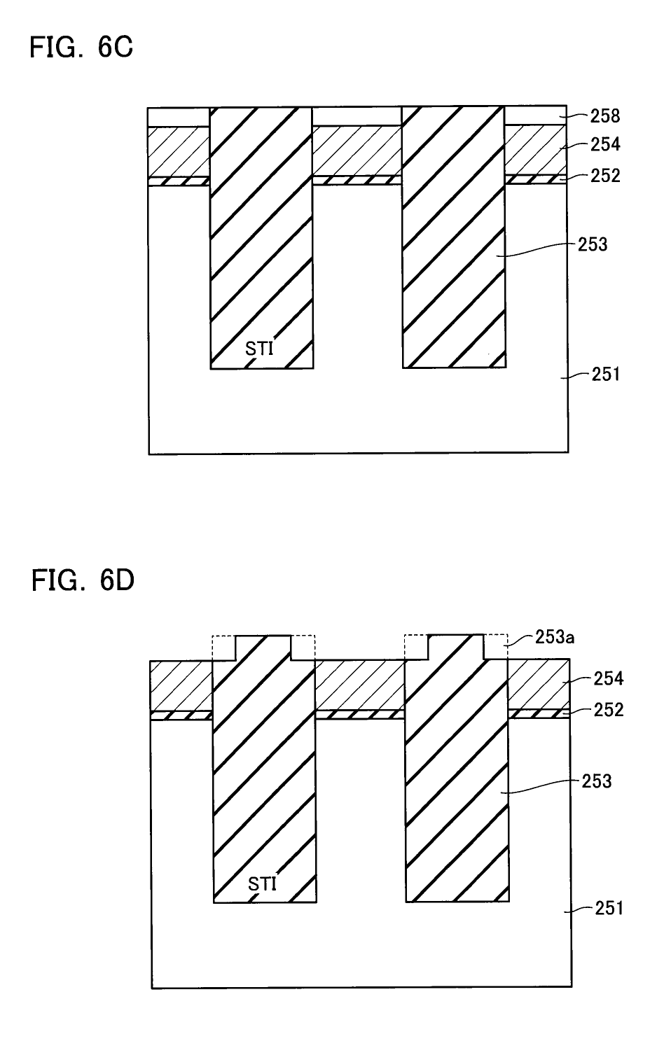

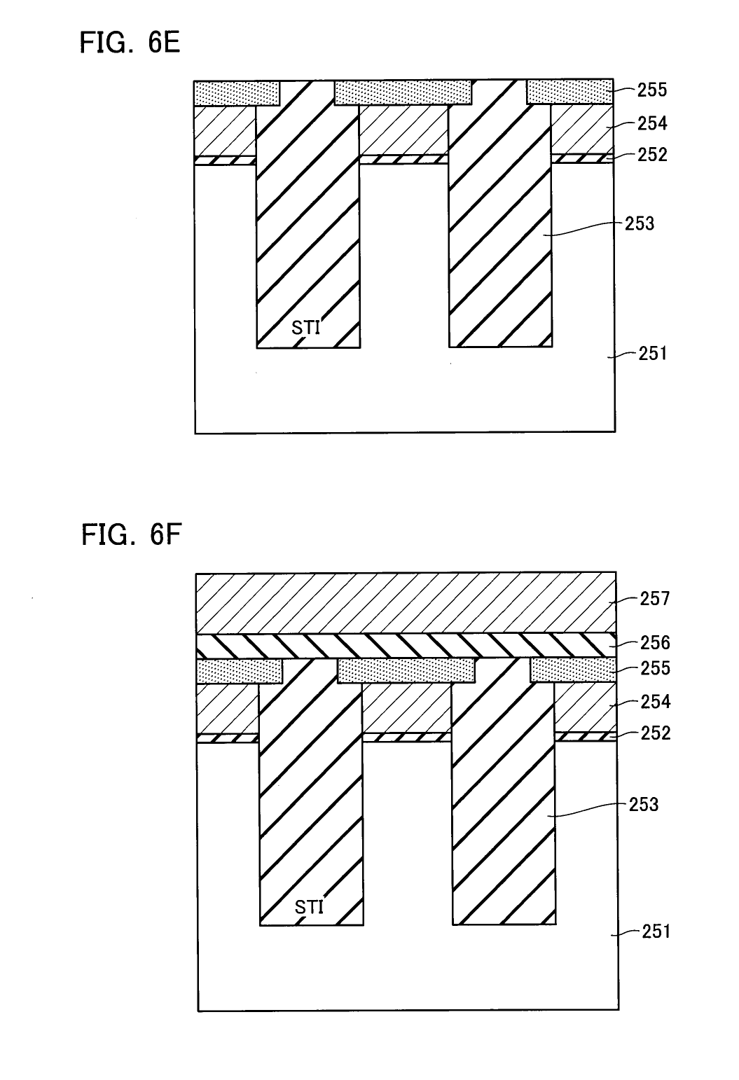

Next, an explanation will be given of the manufacturing method of the memory cell 200 of the nonvolatile semiconductor memory device according to the second embodiment with reference to FIGS. 6A to 6F.

First, as shown in FIG. 6A, an insulating layer 252 which is formed of SiO₂ and which will be a tunnel insulating film a semiconductor layer 254 which is formed of polysilicon and which will be the semiconductor film 204 of the FG, and a dummy layer 258 formed of SiN or the like are successively deposited on a silicon substrate 251.

Next, as shown in FIG. 6B, a plurality of parallel trenches 259 each having a depth reaching the interior of the silicon substrate 251 are formed between adjoining memory cells 200 by RIE.

Subsequently, as shown in FIG. 6C, the buried insulating body 253 which is formed of SiO₂ or the like and which will be the insulating film 203 are buried in the trench 259 to form an STI. Thereafter, the upper face of the buried insulating body 253 is flattened by CMP.

Next, as shown in FIG. 6D, the dummy layer 258 is removed. At this time, a part 253a of the buried insulating body 253 protruding relative to the upper face of the metal layer 254 is also removed.

Subsequently, as shown in FIG. 6E, a metal layer 255 which will be the metal film 205 having a height reaching the topmost face of the buried insulating body 253 is deposited on the buried insulating body 253 and the upper face of the semiconductor layer 254. Thereafter, the upper face of the buried insulating body 253 and that of the metal layer 255 are flattened by CMP. Note that as the metal layer 255, an arbitrary material like WSi can be used.

Finally, as shown in FIG. 6F, an IPD layer 256 which will be the IPD film 206, and a semiconductor layer 257 which is formed of polysilicon and which will be the CG are successively deposited on the flattened buried insulating body 253 and metal layer 255. Like the first embodiment, a stacked layer of, for example, SiN and SiO₂ can be used as the IPD layer 256, and in addition, a highly-dielectric film like HfO₂ or Al₂O₃, a stacked film of those highly-dielectric films, or a stacked film of a highly-dielectric film and SiO₂, SiN or the like can also be used.

In the foregoing explanation, the STI is formed after the tunnel insulating film 202 and the semiconductor film 254 are formed. However, the memory cell 200 can be manufactured even if the tunnel insulating film 202 and the FG are formed after the STI is formed.

### Third Embodiment

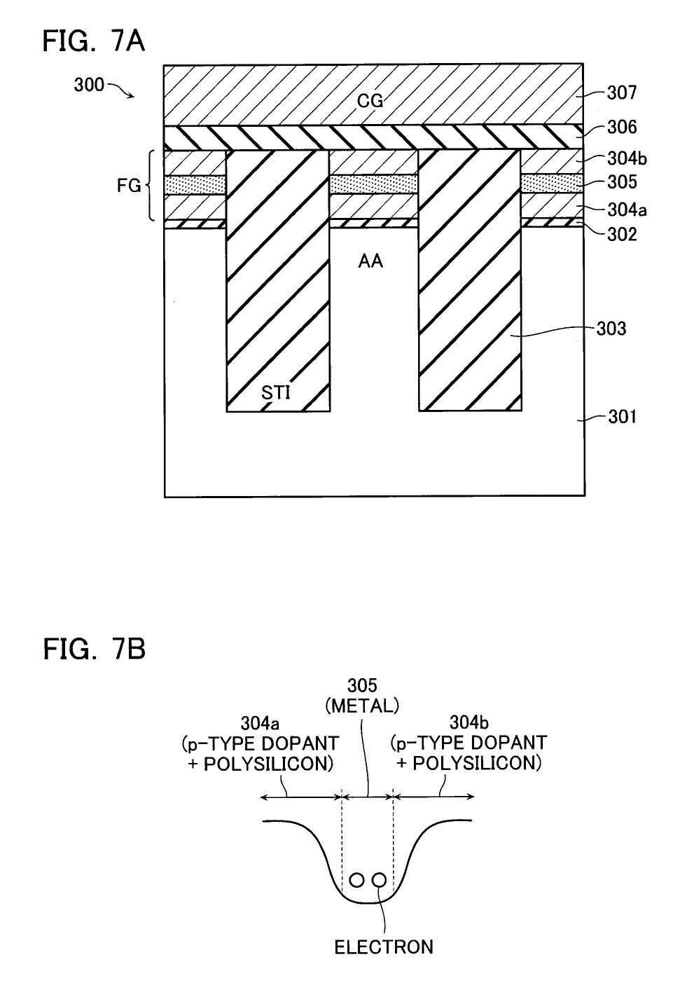

FIG. 7A is a cross-sectional view showing a memory cell 300 of a nonvolatile semiconductor memory device according to the third embodiment.

In the memory cell 300, an FG has a first semiconductor film 304a, a metal film 305, and a second semiconductor film 304b stacked together between a tunnel insulating film 302 and an IPD film 306. Other structures are same as those of the memory cell 100 of the first embodiment.

The FG having such a structure allows arbitrary setting of the film thicknesses of the first and second semiconductor films 304a, 304b and the dopant concentration thereof. For example, as shown in FIG. 7B, when the first and second semiconductor films 304a, 304b are polysilicon in which boron (B) is doped as a p-type dopant and the metal film 305 is a metal having a work function near the conduction band of polysilicon, the potential in the metal film 305 of the FG decreases and the stability of electron increases, so that good retention characteristics can be achieved. The concentration of boron in polysilicon can be set arbitrary, but a high concentration like 10²⁰ cm⁻³ or so is desirable. The foregoing metal can be selected arbitrary, but in order to stabilize electrons in the FG, for example, a metal having a work function near the conduction band like W or Pt is desirable. When the concentration of the p-type dopant in polysilicon is sufficiently high, a metal having a work function near the center of the band gap like NiSi or TiN can also be used.

In the foregoing explanation, the FG has a structure in such a way that the potential of electron in the metal film 305 is reduced by selecting a work function between the first and second semiconductor films 304a, 304b and the metal film 305. However, if a p-type dopant is doped in the first semiconductor film 304a, an n-type dopant is doped in the second semiconductor film 304b, and the work function of the metal film 305 is set to be near the conduction band, it is possible to prevent electrons written in the FG from coming into a silicon substrate 301 through the tunnel insulating film 302. Conversely, electric field strength applied to the tunnel insulating film 302 at the time of write operation can be enhanced if an n-type dopant is doped in the first semiconductor film 304a, resulting in improvement of a write operation speed. Those indicate that a device designing according to its purpose becomes possible by adjusting the concentration of the dopant of the first semiconductor film 304a. While at the same time, it is also possible to prevent electrons from coming into the CG 307 through the insulating film 302 by adjusting the kind of the dopant doped in the second semiconductor film 304b and the concentration thereof.

The foregoing explanation has been given of a case in which the first and second semiconductor films 304a, 304b are formed of polysilicon, but SiGe, SiC and a composite semiconductor like GaAs or InP can be used.

In the foregoing explanation, the first and second semiconductor films 304a, 304b are formed of the same material (polysilicon). However, it is desirable to individually use an appropriate material in accordance with a work function and a band structure.

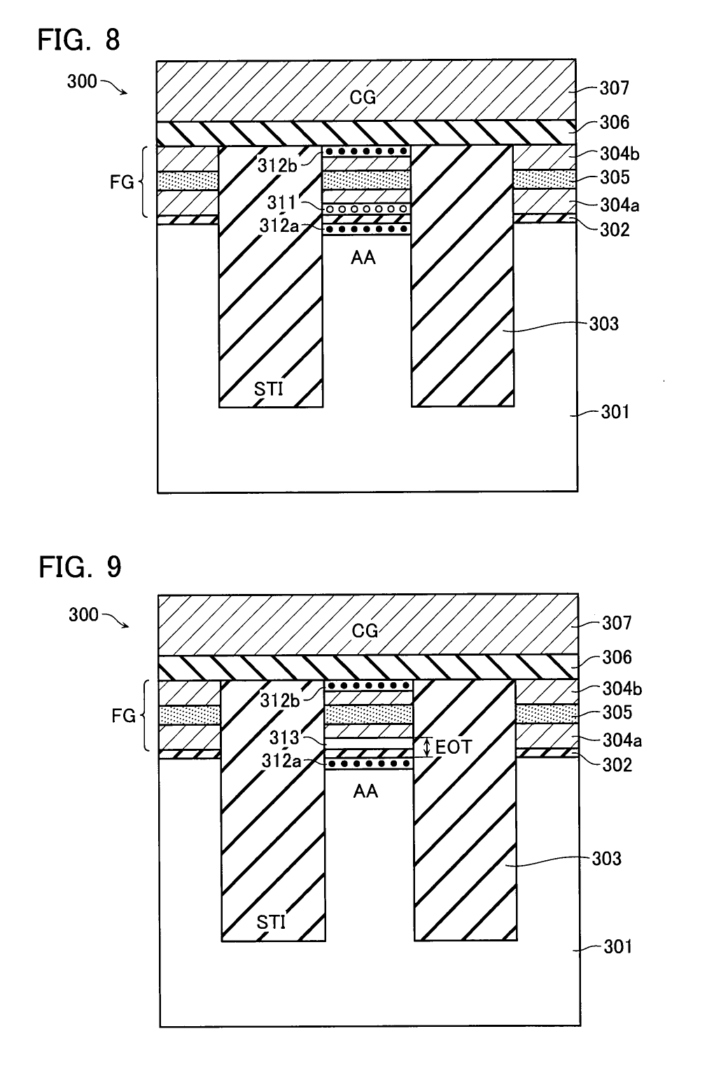

FIGS. 8 and 9 are diagrams showing conditions at the time of write operation and at the time of read operation in the nonvolatile semiconductor memory device of the third embodiment.

In the memory cell 300, polysilicon in which an n-type dopant is doped is used as the first and second semiconductor films 304a, 304b. The concentration of the dopant is set in such away that an inversion layer 311 is formed in the first semiconductor film 304a at the tunnel-insulting-film-302 side at the time of write operation (FIG. 8), and the inversion layer 311 is not formed at the time of read operation (FIG. 9). In this case, the effective tunneling thickness EOT at the time of write operation and at the time of read operation can be changed, thereby realizing the memory cell having good write operation characteristics and retention characteristics.

### Fourth Embodiment

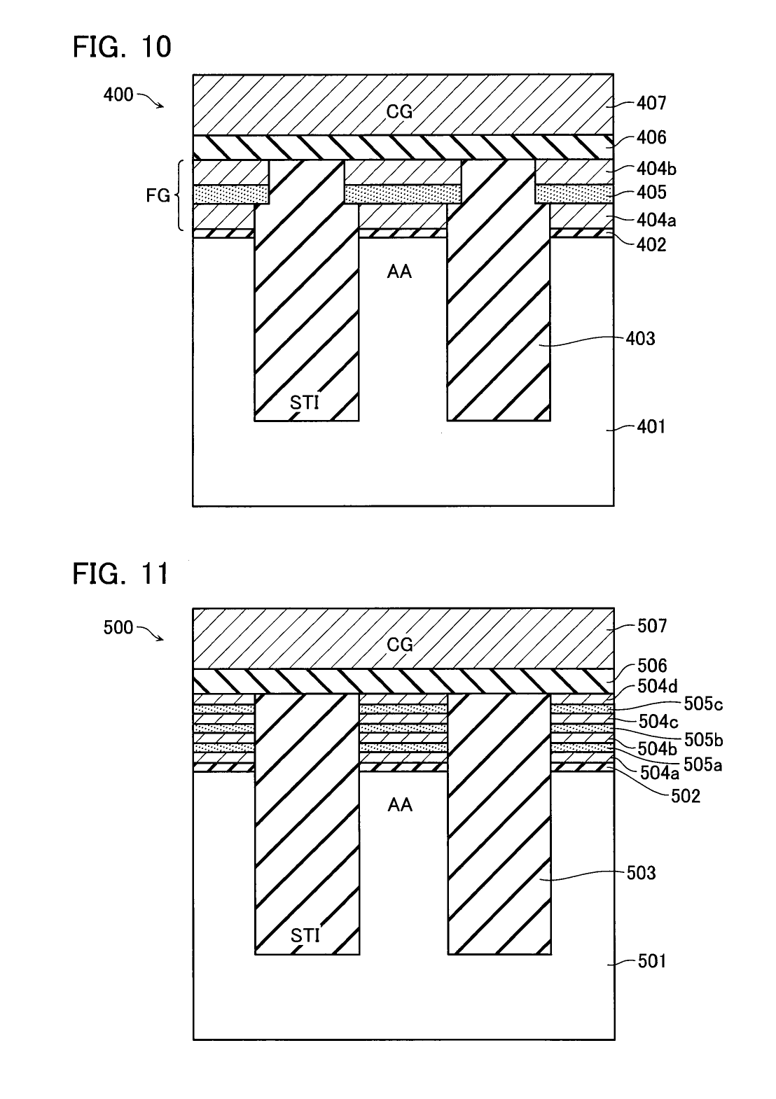

FIG. 10 is a cross-sectional view showing a memory cell 400 of a nonvolatile semiconductor memory device according to the fourth embodiment.

In the memory cell 400, an FG has a first semiconductor film 404a, a metal film 405, and a second semiconductor film 404b stacked together between a tunnel insulating film 402 and an IPD film 406. Moreover, the metal film 405 and the second semiconductor film 404b near the IPD film 406 have a wider width than that of the first semiconductor film 404 near the tunnel insulating film 402. Other structures are same as those of the memory cell 100 of the first embodiment.

The FG having such a structure allows achievement of the same effect as that of the third embodiment. As the second semiconductor film 404b and the metal film 405 of the FG are made wider than the first semiconductor film 404a, an area where the FG and a CG face with each other becomes larger than an area where the FG and an AA face with each other. As a result, the capacitance between the FG and the CG becomes larger than the capacitance between the FG and the AA, so that the capacitive coupling ratio Cr can be set larger than that of the third embodiment.

### Fifth Embodiment

FIG. 11 is a cross-sectional view showing a memory cell 500 of a nonvolatile semiconductor memory device according to the fifth embodiment.

In the memory cell 500, an FG has semiconductor films 504 and metal films 505 stacked together in a multiple layer manner between a tunnel insulating film 502 and an IPD film 506. More specifically, a first semiconductor film 504a, a metal film 505a, a semiconductor film 504b, a metal film 505b, a semiconductor film 504c, a metal film 504c, and a second semiconductor film 504d are stacked together. Other structures are same as those of the memory cell 100 of the first embodiment. In this case, for example, a material of the metal film 505 near the tunnel insulating film 502 and the IPD film 506 is selected from ones having a work function near the valence band, and a material of the metal film 505 more closer to the center of the FG is selected from ones having a work function near the conduction band, so that the electron concentration of the FG can be so adjusted as to become the highest at the time of retention.

As explained above, according to the fifth embodiment, by setting the work function of each metal film 505, it is possible to form the FG having a potential structure in accordance with its purpose.

### Sixth Embodiment

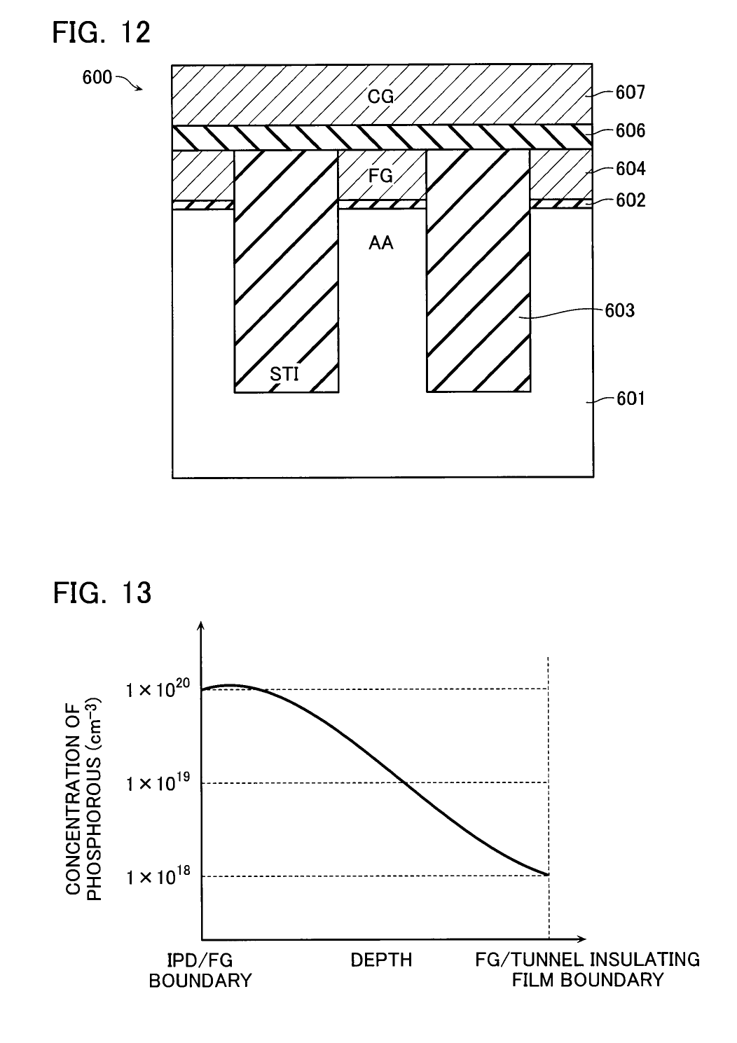

FIG. 12 is a cross-sectional view showing a memory cell 600 of a nonvolatile semiconductor memory device according to the sixth embodiment.

All of the FGs of the memory cells of the first to fifth embodiments have the metal film (in the case of the first embodiment, denoted by a number 105 in FIG. 1). In the sixth embodiment, the FG of the memory cell 600 comprises a semiconductor film 604 only. Regarding a dopant doped in the semiconductor film 604, however, a predetermined concentration gradient is set from a boundary (hereinafter, “IPD/FG boundary”) between an IPD and the FG to a boundary (hereinafter, “FG/tunnel insulating film boundary”) between the FG and the tunnel insulating film.

FIG. 13 shows an example of the concentration of a dopant doped in the FG.

According to this example, the concentration of phosphorous which is a dopant is 1×10²⁰ cm⁻³ or so in the vicinity of the IPD/FG boundary, and becomes 1×10¹⁸ cm⁻³ or so toward the FG/tunnel insulating film boundary. The concentration of phosphorous in the vicinity of the tunnel insulating film is set to be less than a concentration or equal that an inversion layer is formed in the vicinity of the tunnel insulating film 602 at the time of write operation, and is set to be higher than a concentration that the inversion layer is not formed in the vicinity of the tunnel insulating film 602 at the time of read operation. Setting such a dopant concentration enables improvement of the retention characteristics of the memory cell without deteriorating the write operation characteristics. Note that regarding the concentration of a dopant doped in the FG, it is fine that such a concentration is set to be lower in the vicinity of the tunnel insulating film than a part in the vicinity of the IPD, and as shown in FIG. 13, it is preferable to set such a concentration to be 1×10¹⁸ cm⁻³ to 3×10¹⁹ cm⁻³ or so in the vicinity of the tunnel insulating film 602, and to be equal to 5×10¹⁹ cm⁻³ or greater in the vicinity of the IPD.

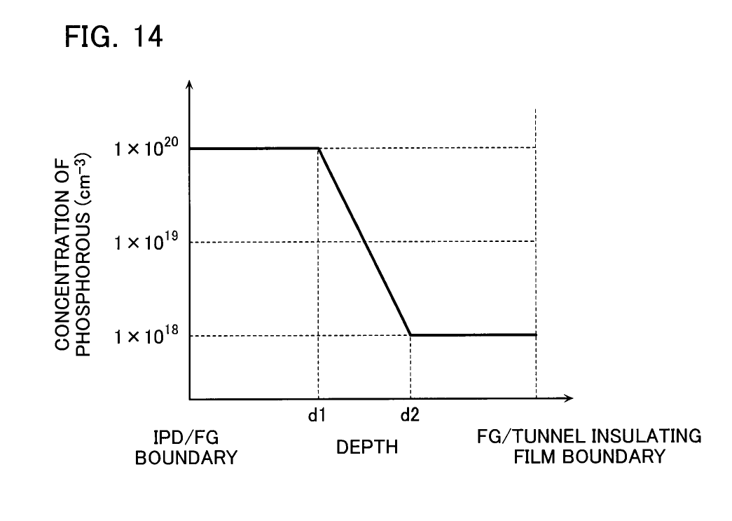

As shown in FIG. 13, regarding the concentration of a dopant doped in the FG, it is not necessary to smoothly reduce such a concentration from the IPD/FG boundary toward the FG/tunnel insulating film boundary. As shown in FIG. 14, a concentration gradient is set in such a way that the concentration of phosphorous is constantly 1×10²⁰ cm⁻³ at an area from the IPD/FG boundary to a predetermined depth d1, is constantly 1×10²⁰ cm⁻³ at an area from the FG/tunnel insulating film boundary to a predetermined depth d2, and is from 1×10²⁰ cm⁻³ to 1×10¹⁸ cm⁻³ at an area from the depth d1 to the depth d2.

In this case, like the case shown in FIG. 13, an inversion layer is formed in the vicinity of the tunnel insulating film 602 at the time of write operation, and such an inversion layer is not formed in the vicinity of the tunnel insulating film 602 at the time of read operation.

As explained above, according to the sixth embodiment, by setting the concentration of the dopant of the FG in the vicinity of the tunnel insulating film 602 to be lower than the concentration in the vicinity of the IPD, the retention characteristics can be improved in comparison with a case in which the FG is formed with a uniform dopant concentration.

Note that the sixth embodiment can be applied to a case in which the FG has a metal film like the first embodiment.

Although the embodiments of the invention have been described above by way of example, the invention is not limited to the embodiments. Various changes and additions can be made without departing from the scope of the invention.

What is claimed is:

1. A nonvolatile semiconductor memory device comprising a memory cell, the memory cell including:
a semiconductor substrate;
a first gate insulating film formed on the semiconductor substrate;
a floating gate formed on the first gate insulating film;
a second gate insulating film formed on the floating gate; and
a control gate formed on the second gate insulating film,
the floating gate comprising a first semiconductor film contacting the first gate insulating film, and a metal film stacked on the first semiconductor film, and
an effective tunneling thickness between the semiconductor substrate and the floating gate in a read operation being thicker than an effective tunneling thickness between the semiconductor substrate and the floating gate in a write operation.

2. The device of claim 1, wherein the metal film of the floating gate has a larger cross-sectional area orthogonal to a stack direction than a cross-sectional area of the first semiconductor film of the floating gate.

3. The device of claim 1, wherein the floating gate further comprises a second semiconductor film stacked on the metal film.

4. The device of claim 3, wherein the metal film of the floating gate is formed of a metal having a work function substantially equal to a conduction band of the first and second semiconductor films.

5. The device of claim 4, wherein the first and second semiconductor films of the floating gate are each formed of polysilicon in which a p-type dopant is doped.

6. The device of claim 4, wherein the first and second semiconductor films of the floating gate are each formed of a composite semiconductor.

7. The device of claim 4, wherein one of the first and second semiconductor films of the floating gate is formed of polysilicon in which an n-type dopant is doped, while another is formed of polysilicon in which a p-type dopant is doped.

8. The device of claim 3, wherein the metal film of the floating gate and the second semiconductor film thereof have a larger cross-sectional area orthogonal to a stack direction than a cross-sectional area of the first semiconductor film of the floating gate.

9. The device of claim 3, wherein the floating gate further comprises at least one stacked body arranged between the metal film and the second semiconductor film, the stacked body including another metal film and another semiconductor film.

10. The device of claim 1, wherein a concentration of a dopant in the first semiconductor film of the floating gate is substantially equal to a concentration or less that an inversion layer is formed in the vicinity of the first gate insulating film in write operation, and is higher than a concentration that the inversion layer is not formed in the vicinity of the gate insulating film in read operation.

11. A nonvolatile semiconductor memory device comprising a memory cell, the memory cell including:
a semiconductor substrate;
a first gate insulating film formed on the semiconductor substrate;
a floating gate formed on the first gate insulating film;
a second gate insulating film formed on the floating gate; and
a control gate formed on the second gate insulating film,
the floating gate comprising a first semiconductor film contacting the first gate insulating film, and a metal film stacked on the first semiconductor film, and
a concentration of a dopant in the first semiconductor film of the floating gate is substantially equal to or less than a concentration that causes an inversion layer to be formed in the vicinity of the first gate insulating film in a write operation, and is higher than a concentration that does not cause the inversion layer to be formed in the vicinity of the first gate insulating film in a read operation.

12. The device of claim 11, wherein a cross-sectional area orthogonal to the stack direction of the metal film of the floating gate is larger than a cross-sectional area orthogonal to the stack direction of the first semiconductor film of the floating gate.

13. The device of claim 11, wherein the floating gate further comprises a second semiconductor film stacked on the metal film.

14. The device of claim 13, wherein a cross-sectional area orthogonal to the stack direction of the second semiconductor film of the floating gate is larger than a cross-sectional area orthogonal to the stack direction of the first semiconductor film of the floating gate.

15. The device of claim 13, wherein the floating gate further comprises at least one stacked body arranged between the metal film and the second semiconductor film, the stacked body including another metal film and another semiconductor film.

16. The device of claim 15, wherein a work function of the metal film on the first gate insulating film is closer to a valence band than a work function of another metal film of the stacked body arranged closer to a center in the stack direction of the floating gate.

17. A nonvolatile semiconductor memory device comprising a memory cell, the memory cell including:
a semiconductor substrate;
a first gate insulating film formed on the semiconductor substrate;
a floating gate formed on the first gate insulating film;
a second gate insulating film formed on the floating gate; and
a control gate formed on the second gate insulating film, and
the floating gate having a part in which a dopant is doped at a higher concentration in the vicinity of the second gate insulting film than another part in the vicinity of the first gate insulating film.

18. The device of claim 17, wherein the concentration of the dopant in the floating gate successively changes from a boundary with the first gate insulating film to a boundary with the second gate insulating film.

19. The device of claim 17, wherein the concentration of the dopant in the floating gate is constant from a boundary with the first gate insulating film to a boundary with the second gate insulating film.

20. The device of claim 17, wherein a concentration of the dopant in the part of the floating gate in the vicinity of the first gate insulating film is substantially equal to or less that causes an inversion layer to be formed in the vicinity of the first gate insulating film in write operation, and is higher than a concentration that does not cause the inversion layer to be formed in the vicinity of the first gate insulating film in read operation.
